(19) United States
(12) Patent Application Publication
(10) Pub. No.: US 2026/0190720 A1
(43) Pub. Date: Jul. 2, 2026

(54) Touch Display Device and Display Panel

(71) Applicant: LG Display Co., Ltd., Seoul (KR)

(72) Inventor: Jongmoo Ha, Paju-si (KR)

(21) Appl. No.: 19/215,972

(22) Filed: May 22, 2025

(30) Foreign Application Priority Data
Dec. 31, 2024 (KR) 10-2024-0202013

(51) Int. Cl. H10K 59/131; G06F 3/041; G06F 3/044; G09G 3/3233; H10K 59/122; H10K 59/40

(52) U.S. Cl. CPC H10K 59/1315; G06F 3/0412; G06F 3/04164; G06F 3/0448; G09G 3/3233; H10K 59/122; H10K 59/40; G09G 2310/08; G09G 2320/0247; G09G 2320/066

(57) ABSTRACT

A touch display panel includes a substrate, a driving transistor formed on the substrate, and a light emitting element corresponding to the driving transistor on the driving transistor. The light emitting element comprises an anode electrode formed in an emission area in which a portion of a bank is open, an emission layer contacting the anode electrode in the emission area, and a cathode pattern electrode formed to cover N×M (N, M are natural numbers greater than or equal to 2) light emitting elements along an upper surface of the bank, and contacting the emission layer in the emission area, wherein the cathode pattern electrode is electrically separated from an adjacent cathode pattern electrode by an undercut electrode formed in an undercut area of the bank, and wherein an electrical signal is applied through a cathode pattern line electrically connected to the cathode pattern electrode.

### CROSS REFERENCE TO RELATED APPLICATION

This application claims priority from Republic of Korea Patent Application No. 10-2024-0202013, filed on Dec. 31, 2024, which is hereby incorporated by reference in its entirety.

### TECHNICAL FIELD

Embodiments of the present disclosure relate to a touch display device and a display panel, and more specifically, to a touch display device and a display panel capable of simplifying a touch electrode structure and improving signal transmission efficiency.

### BACKGROUND

As information technology develops, the market for display devices, which are a connecting medium between users and information, is growing. Accordingly, there is increasing the use of various display devices such as organic light emitting display devices (OLED), quantum dot display devices (QDD), liquid crystal display devices (LCD), and plasma display panels (PDP).

Among these display devices, an organic light emitting display device utilizes an organic light emitting diode which is a self-luminous light emitting element, and thus has advantages in terms of fast response speed, contrast ratio, luminance, and viewing angle.

The display device may include light emitting elements arranged in each of a number of subpixels arranged on a display panel and control the luminance of each subpixel by controlling a voltage flowing to the light emitting elements to emit light, thereby displaying an image.

In order to provide more diverse functions, these display devices provide a function that recognizes a touch of the user's finger or pen on the display panel and performs input processing based on the recognized touch.

The touch display device with touch function is expanding its scope of use to not only mobile devices such as smartphones and tablet personal computers (PCs), but also large-screen touch display devices such as automobile displays and exhibition displays.

However, since the touch display device includes both a subpixel array for displaying a video or an image and a touch electrode for touch sensing, there is a problem that the structure becomes complicated.

In particular, if the subpixel array and the touch electrode are arranged to overlap with each other, a part of the light emitted from the subpixel array may be blocked by the touch electrode, resulting in a phenomenon of a decrease of the viewing angle.

### SUMMARY

Embodiments of the present disclosure may provide a touch display device and a display panel capable of simplifying the touch electrode structure and improving a transmission efficiency of touch signals.

Embodiments of the present disclosure may provide a touch display device and a display panel capable of simplifying the touch structure by using a cathode pattern electrode group as a touch electrode.

Embodiments of the present disclosure may provide a touch display device and a display panel capable of reducing cathode resistance and improving transmission efficiency of cathode signals by arranging cathode link lines adjacent to cathode pattern electrodes.

The objects of the embodiments of the present disclosure are not limited to the objects described in the present disclosure, and other objects not mentioned will be clearly understood by those skilled in the art from the description below.

Embodiments of the present disclosure may provide a touch display panel including a substrate, a driving transistor formed on the substrate, and a light emitting element corresponding to the driving transistor on the driving transistor, wherein the light emitting element comprises an anode electrode formed in an emission area in which a portion of a bank is open, an emission layer contacting the anode electrode in the emission area, and a cathode pattern electrode formed to cover N×M (N, M are natural numbers greater than or equal to 2) light emitting elements along an upper surface of the bank, and contacting the emission layer in the emission area, wherein the cathode pattern electrode is electrically separated from an adjacent cathode pattern electrode by an undercut electrode formed in an undercut area of the bank, and wherein an electrical signal is applied through a cathode pattern line electrically connected to the cathode pattern electrode.

Embodiments of the present disclosure may provide a touch display device including a display panel including a substrate, a driving transistor formed on the substrate, and a light emitting element corresponding to the driving transistor on the driving transistor, a driving circuit for supplying a driving signal to the display panel, a switch circuit for supplying a pixel low-potential voltage or a touch driving signal to the display panel, and a timing controller for controlling the driving circuit and the switch circuit, wherein the light emitting element comprises an anode electrode formed in an emission area in which a portion of a bank is open, an emission layer contacting the anode electrode in the emission area, and a cathode pattern electrode formed to cover N×M (N, M are natural numbers greater than or equal to 2) light emitting elements along an upper surface of the bank, and contacting the emission layer in the emission area, wherein the cathode pattern electrode is electrically separated from an adjacent cathode pattern electrode by an undercut electrode formed in an undercut area of the bank, and wherein the pixel low-potential voltage or the touch driving signal is applied to the cathode pattern electrode through a cathode pattern line.

According to embodiments of the present disclosure, it is possible to provide a touch display device and a display panel capable of simplifying the touch electrode structure and improving a transmission efficiency of touch signals.

According to embodiments of the present disclosure, it is possible to provide a touch display device and a display panel capable of simplifying the touch structure and implementing process optimization by using a cathode pattern electrode group as a touch electrode.

According to embodiments of the present disclosure, it is possible to provide a touch display device and a display panel capable of reducing cathode resistance and transmitting low-power cathode signals by arranging cathode link lines adjacent to cathode pattern electrodes.

The effects of the embodiments of the present disclosure are not limited to the effects mentioned above, and other effects not mentioned will be clearly understood by those skilled in the art from the description of the claims.

### BRIEF DESCRIPTION OF THE DRAWINGS

The present disclosure will be more fully understood from the detailed description and accompanying drawings provided below, which are provided for illustration only and are not intended to limit the present disclosure.

FIG. 1 is a schematic diagram illustrating a display device according to embodiments of the present disclosure.

FIG. 2 illustrates a planar structure of a display panel in a touch display device according to embodiments of the present disclosure.

FIG. 3 illustrates a subpixel circuit in a touch display device according to embodiments of the present disclosure.

FIG. 4 schematically illustrates a touch sensing structure in a touch display device according to embodiments of the present disclosure.

FIG. 5 illustrates a cross-section of an area where a cathode pattern electrode is formed in a display device according to embodiments of the present disclosure.

FIG. 6 is a cross-sectional diagram illustrating an undercut area of FIG. 5 in a touch display device according to embodiments of the present disclosure.

FIG. 7 illustrates a cross-section of an area where a cathode pattern electrode is formed in a display device according to another embodiment of the present disclosure.

FIG. 8 illustrates a cross-section of an area where a cathode pattern electrode is formed in a display device according to another embodiment of the present disclosure.

FIG. 9 illustrates an example of a case in which a cathode pattern electrode is separated through an undercut structure at the bottom of a bank in a display device according to another embodiment of the present disclosure.

FIG. 10 is a cross-sectional view of an undercut area of FIG. 8 in a touch display device according to another embodiment of the present disclosure.

FIG. 11 illustrates an example of a cross-section in a case in which a cathode pattern electrode is separated through an undercut structure at the bottom of a bank in a display device according to another embodiment of the present disclosure.

FIG. 12 illustrates a cross-section of a display device in which an undercut structure and a cathode pattern line are formed at the bottom of a bank according to another embodiment of the present disclosure.

FIG. 13 illustrates a signal applied to a cathode pattern electrode for time division driving in a touch display device according to embodiments of the present disclosure.

FIG. 14 illustrates a touch sensing structure having a different extension direction of a cathode pattern line in a touch display device according to embodiments of the present disclosure.

### DETAILED DESCRIPTION

Hereinafter, some embodiments of the present disclosure will be described in detail with reference to exemplary drawings. In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,”next“before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompass all the meanings of the term “can”.

Hereinafter, various embodiments of the present disclosure will be described in detail with reference to the accompanying drawings.

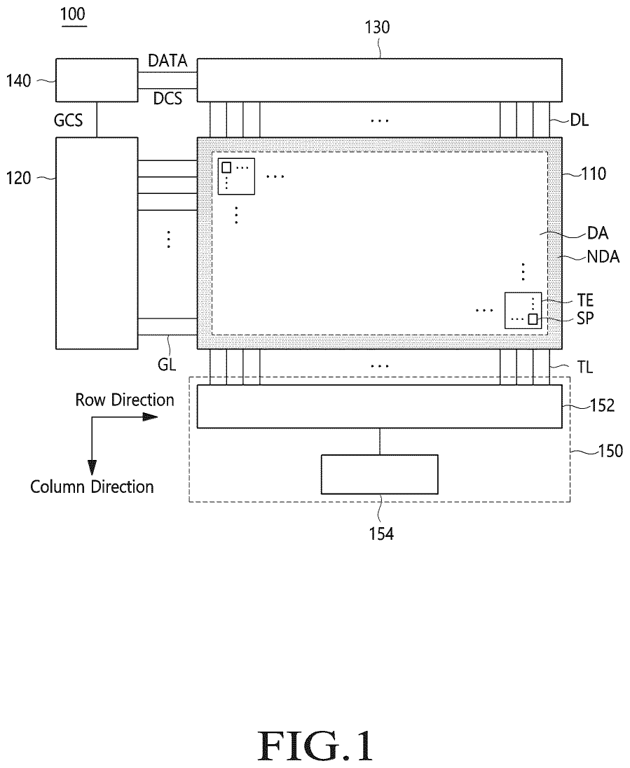

FIG. 1 illustrates a schematic configuration of a touch display device 100 according to embodiments of the present disclosure.

Referring to FIG. 1, a display device 100 according to embodiments of the present disclosure may include, as components for displaying images, a display panel 110, a gate driving circuit 120, a data driving circuit 130, and a timing controller 140.

The display panel 110 may include a display area DA where an image is displayed and a non-display area NDA where an image is not displayed.

The non-display area NDA may be an outer area of the display area DA and may also be referred to as a bezel area. The non-display area NDA may be an area visible from the front of the touch display device 100 or may be an area that is bent and not visible from the front of the touch display device 100.

The display panel 110 may include a plurality of subpixels SP. For example, the touch display device 100 may be various types of display devices including a liquid crystal display device, an organic light-emitting display device, a micro light-emitting diode (LED) display device, a quantum dot display device, etc.

The structure of each of the plurality of subpixels SP may vary depending on the type of the touch display device 100. For example, if the touch display device 100 is a self-luminous display device in which the subpixels SP emit light by themselves, each subpixel SP may include a self-luminous light emitting element, one or more transistors, and one or more capacitors.

In addition, the display panel 110 may further include various types of signal lines in order to drive a plurality of subpixels SP. For example, the various types of signal lines may include a plurality of data lines DL that transmit data voltages and a plurality of gate lines GL that transmit gate signals.

The plurality of data lines DL and the plurality of gate lines GL may intersect each other. Each of the plurality of data lines DL may be arranged while extending in a column direction. Each of the plurality of gate lines GL may be arranged while extending in a row direction.

Here, the column direction and the row direction are relative. For example, the column direction may be a vertical direction and the row direction may be a horizontal direction. For another example, the column direction may be horizontal and the row direction may be vertical.

The data driving circuit 130 is a circuit for driving a plurality of data lines DL and may output data signals to a plurality of data lines DL) The gate driving circuit 120 is a circuit for driving a plurality of gate lines GL and may output gate signals to a plurality of gate lines GL.

The timing controller 140 is a device for controlling the data driving circuit 130 and the gate driving circuit 120, and may control the driving timing for a plurality of data lines DL and the driving timing for a plurality of gate lines GL.

The timing controller 140 may supply various types of data driving control signals DCS to the data driving circuit 130 to control the data driving circuit 130 and may supply various types of gate driving control signals GCS to the gate driving circuit 120 to control the gate driving circuit 120.

The gate driving circuit 120 may supply a gate signal to a plurality of gate lines GL according to the timing control of the timing controller 140. The gate driving circuit 120 may receive a first gate voltage corresponding to a turn-on level voltage and a second gate voltage corresponding to a turn-off level voltage together with various gate driving control signals GCS, generate a gate signal, and supply the generated gate signal to a plurality of gate lines GL. Here, the turn-on level voltage may be a high level voltage, and the turn-off level voltage may be a low level voltage. Alternatively, the turn-on level voltage may be a low level voltage, and the turn-off level voltage may be a high level voltage.

The data driving circuit 130 may supply data voltages to a plurality of data lines DL according to the driving timing control of the timing controller 140. The data driving circuit 130 may receive image data DATA in digital form from the timing controller 140, convert the received image data DATA into data voltages in analog form, and output the converted image data to a plurality of data lines DL.

The touch display device 100 may include a touch circuit 150 that detects an occurrence of a touch by a touch object such as a finger or a pen located on the display panel 110 or detects a touch position in order to provide not only an image display function but also a touch sensing function.

The touch circuit 150 may include a touch driving circuit 152 that generates touch sensing data by driving and sensing a touch electrode TE, and a touch controller 154 that can detect touch occurrence or detect a touch position using the touch sensing data.

The display panel 110 may include a plurality of touch electrodes TE as touch sensors. In addition, the display panel 110 may further include a plurality of touch lines TL for electrically connecting the plurality of touch electrodes TE and the touch driving circuit 152. The touch electrode TE may be also referred to as a touch sensor.

If the touch electrode TE exists inside the display panel 110, the touch electrode TE may be formed inside the display panel 110 during the manufacturing process of the display panel 110.

The touch driving circuit 152 may supply a touch driving signal to at least one of the plurality of touch electrodes TE, and detect a touch sensing signal transmitted from at least one of the plurality of touch electrodes TE to generate touch sensing data.

The touch circuit 150 may perform touch sensing in a self-capacitance sensing manner or a mutual-capacitance sensing manner.

If the touch circuit 150 performs touch sensing in a self-capacitance sensing manner, the touch circuit 150 may perform touch sensing based on the capacitance between each touch electrode TE and a touch object (e.g., a finger, a pen, etc.).

If the touch circuit 150 performs touch sensing in a mutual-capacitance sensing manner, the touch circuit 150 may perform touch sensing based on the capacitance between the touch electrodes TE.

According to the mutual-capacitance sensing manner, a plurality of touch electrodes TE may be divided into a touch driving electrode and a touch sensing electrode. The touch driving circuit 152 may drive the touch driving electrode using a touch driving signal and detect a touch sensing signal from the touch sensing electrode.

According to the self-capacitance sensing manner, each of the plurality of touch electrodes TE may act as both a touch driving electrode and a touch sensing electrode. The touch driving circuit 152 may drive all or part of the plurality of touch electrodes TE and sense all or part of the plurality of touch electrodes TE.

The touch driving circuit 152 and the touch controller 154 may be implemented as separate devices or as a single device.

Alternatively, the touch driving circuit 152 and the data driving circuit 130 may be implemented as separate integrated circuits. Alternatively, the entirety or part of the touch driving circuit 152 and the entirety or part of the data driving circuit 130 may be integrated with each other and implemented as a single integrated circuit.

The touch display device 100 according to the embodiments of the present disclosure may be a self-luminous display device in which a self-luminous light emitting element is arranged on the display panel 110, such as an organic light-emitting display device, a quantum dot display device, a micro LED display device, etc.

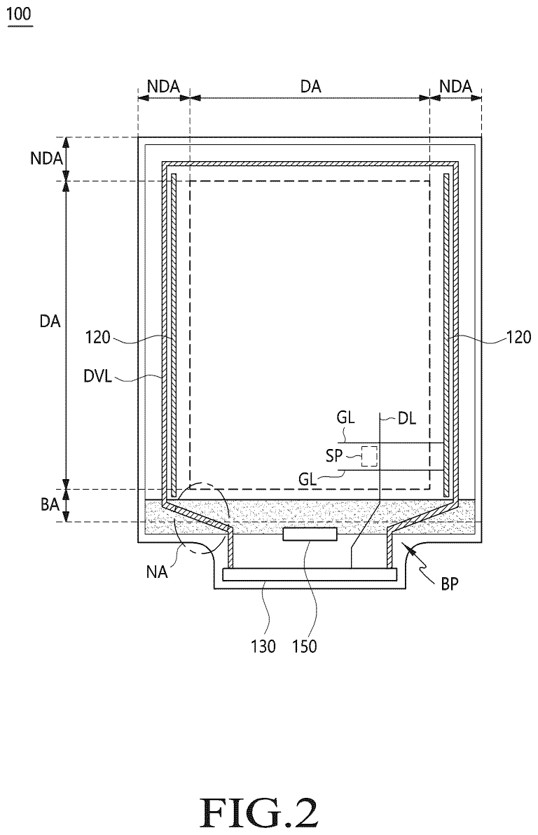

FIG. 2 illustrates an example of a planar structure of a display panel in a touch display device according to the embodiments of the present disclosure.

Referring to FIG. 2, in the touch display device 100 according to the embodiments of the present disclosure, the display panel 110 may include a rectangular flexible back plate BP. The back plate BP may be divided into a display area DA and a non-display area NDA. The display area DA is an area that directly displays an image and is arranged in the center of the back plate BP. The non-display area NDA is arranged around the display area DA and is an area where driving elements required to drive display devices arranged in the display area DA are arranged.

Light emitting elements and transistors for driving the light emitting elements may be formed in the display area DA. The gate driving circuit 120 and the data driving circuit 130 required to perform a display function may be disposed in the non-display area NDA.

The gate driving circuit 120 may supply a scan signal to a subpixel SP through a gate line GL. The gate driving circuit 120 may be formed simultaneously with the transistors formed in the display area DA.

Here, the structure in which the gate driving circuit 120 is arranged on both sides of the display panel 110 is illustrated, but the gate driving circuit 120 may be arranged on only one side of the display area DA.

In addition, there is illustrated a case in which the gate driving circuit 120 is mounted in the form of a gate-in-panel (GIP) inside the display panel 110. However, the gate driving circuit 120 may also be formed in a structure in which the gate driving circuit 120 is mounted on a printed circuit board and coupled to the display panel 110.

The data driving circuit 130 may supply a data voltage to the subpixels SP through the data line DL. In addition, the data driving circuit 130 may supply a driving voltage to the subpixels SP through the driving voltage line DVL. The data line DL may be arranged in the column direction in the display area DA. The driving voltage line DVL may be arranged around the edge of the display area DA to minimize signal delay in order to supply the same level of driving voltage to all subpixels SP.

The driving voltage supplied through the driving voltage line DVL may be transmitted to an internal signal line (not shown) arranged in the row direction or the column direction in the display area DA. The driving voltage supplied through the driving voltage line DVL may be a pixel high-potential voltage EVDD or a pixel low-potential voltage EVSS for driving the subpixel SP.

The data driving circuit 130 may be mounted on the back plate BP or may be mounted on a printed circuit board and coupled with the back plate BP.

The printed circuit board on which the data driving circuit 130 and the touch circuit 150 are positioned may be bent toward the rear of the display panel 110 in a bending area BA.

For example, the bending area BA may be an area between the printed circuit board on which the touch circuit 150 and the data driving circuit 130 are positioned and the display area DA.

In addition, a cover glass having a curved structure may be attached to the front of the display panel 110.

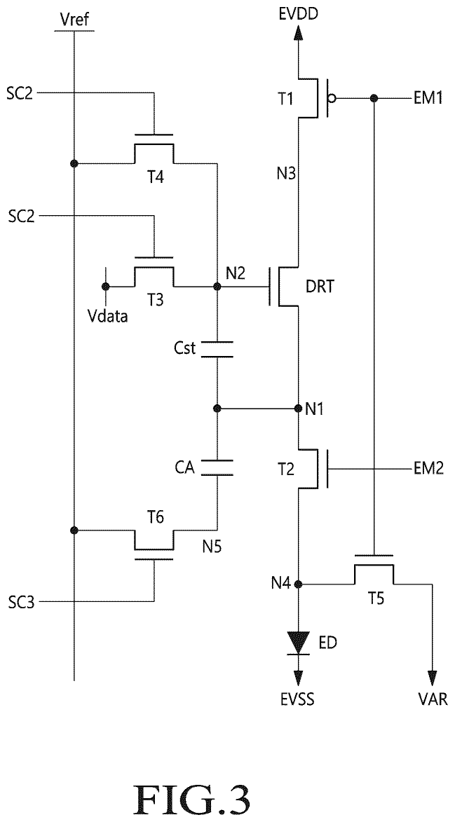

FIG. 3 illustrates an example of a subpixel circuit of a touch display device according to embodiments of the present disclosure.

Referring to FIG. 3, the subpixel circuit of the touch display device 100 according to the embodiments of the present disclosure may include a light emitting element ED, a driving transistor DRT for driving the light emitting element ED, a plurality of switching transistors T1 to T7, and a plurality of capacitors Cst and CA.

The subpixel circuit may be driven in the order of an initialization period, a sensing period, a data writing period, an anode reset period, and an emission period.

The subpixel circuit may be connected to a data line DL to which a data voltage Vdata is applied and gate lines to which gate signals EM1, EM2, SC1, SC2 and SC3 are applied.

In addition, the subpixel circuit may be connected to a pixel high-potential voltage line to which a pixel high-potential voltage EVDD is applied, a pixel low-potential voltage line to which a pixel low-potential voltage EVSS is applied, a reset voltage line to which a reset voltage VAR is applied, and a reference voltage line to which a reference voltage Vref is applied.

All subpixels SP arranged on the display panel 110 may be connected to a constant voltage line in common. In this case, the levels of the constant voltages EVDD, EVSS, VAR and Vref applied to the subpixel circuit may be set in consideration of the voltage margin in the saturation region of the driving transistor DRT. For example, the levels of the constant voltages (e.g., EVDD, EVSS, VAR, Vref) may be set to a condition of EVDD>Vref>VAR>EVSS.

The gate signals (e.g., EM1, EM2, SC1, SC2, SC3) may include pulses that swing between a gate high voltage of a turn-on level and a gate low voltage of a turn-off level. The gate high voltage may be set to a voltage level higher (e.g., greater) than a pixel high-potential voltage EVDD, and the gate low voltage may be set to a voltage level lower (e.g., less) than a pixel low-potential voltage EVSS.

The gate signals may include a first emission signal EM1, a second emission signal EM2, a first scan signal SC1, a second scan signal SC2, and a third scan signal SC3. The first emission signal EM1 may be interpreted as a first gate signal, the second emission signal EM2 may be interpreted as a second gate signal, the first scan signal SC1 may be interpreted as a third gate signal, the second scan signal SC2 may be interpreted as a fourth gate signal, and the third scan signal SC3 may be interpreted as a fifth gate signal, respectively.

The driving transistor DRT may generate current according to a gate-source voltage to drive the light emitting element ED. The driving transistor DRT may include a first electrode connected to a first node N1, a gate electrode connected to a second node N2, and a second electrode connected to a third node N3.

The light emitting element ED may be implemented as an organic light emitting diode (OLED). The light emitting element ED may include an anode electrode, a cathode electrode, and an organic compound layer formed between these electrodes. The anode electrode of the light emitting element ED may be connected to a fourth node N4, and the cathode electrode may be connected to a pixel low-potential voltage line to which a pixel low-potential voltage EVSS is applied.

The organic compound layer may include, but is not limited to, a hole injection layer HIL, a hole transport layer HTL, an emission layer EML, an electron transport layer ETL, and an electron injection layer (EIL).

If a voltage is applied to the anode electrode and the cathode electrode of the light emitting element ED, holes passing through the hole transport layer HTL and electrons passing through the electron transport layer ETL move to the emission layer EML, thereby forming excitons. At this time, visible light is emitted from the emission layer EML. The light emitting element ED may be implemented as a tandem structure in which multiple emission layers are stacked. The light emitting element ED of the tandem structure may improve the brightness and lifespan of the subpixel.

A first capacitor Cst may be connected between the first node N1 and the second node N2. The first capacitor Cst may be initialized during the initialization period, and then store a threshold voltage of the driving transistor DRT during the sensing period. The first capacitor Cst may store the data voltage Vdata compensated for by the threshold voltage of the driving transistor DRT during the data writing period, and then maintain a gate-source voltage of the driving transistor DRT during the anode reset period and the emission period.

A second capacitor CA may be connected between the first node N1 and a seventh switching transistor T7. The second capacitor CA may be charged with a reference voltage Vref if the seventh switching transistor T7 is turned on and may maintain the first node N1 at the reference voltage Vref.

A first switching transistor T1 may be connected between the pixel high-potential voltage line to which the pixel high-potential voltage EVDD is applied and the third node N3 of the driving transistor DRT and may be turned on in response to the first emission signal EM1. If the first switching transistor T1 is turned on, the pixel high-potential voltage EVDD is applied to the third node N3. The first switching transistor T1 may be formed as a P-type transistor and may be turned on when a voltage of the first emission signal EM1 is a gate low voltage.

A second switching transistor T2 may be connected between the first node N1 and the fourth node N4 and may be turned on in response to a second emission signal EM2. If the second switching transistor T2 is turned on, the first node N1 may be connected to the fourth node N4. The second switching transistor T2 may be formed as an N-type transistor and may be turned on when the second emission signal EM2 is a gate high voltage.

A third switching transistor T3 may be connected between the data line to which the data voltage Vdata is applied and the second node N2 and may be turned on in response to a first scan signal SC1. If the third switching transistor T3 is turned on, the data voltage Vdata may be applied to the second node N2 of the driving transistor DRT. The third switching transistor T3 may be formed as an N-type transistor and may be turned on when the first scan signal SC1 is a gate high voltage.

A fourth switching transistor T4 may be connected between the reference voltage line to which the reference voltage Vref is applied and the second node N2 of the driving transistor DRT and may be turned on in response to a second scan signal SC2. If the fourth switching transistor T4 is turned on, the reference voltage Vref may be applied to the second node N2. The fourth switching transistor T4 may be formed as an N-type transistor and may be turned on when the voltage of the second scan signal SC2 is a gate high voltage.

A fifth switching transistor T5 may be connected between a reset voltage line to which a reset voltage VAR is applied and a fourth node N4 and may be turned on in response to the first emission signal EM1. If the fifth switching transistor T5 is turned on, the reset voltage VAR may be applied to the fourth node N4. The fifth switching transistor T5 may be formed as an N-type transistor and may be turned on when the voltage of the first emission signal EM1 is a gate high voltage.

A sixth switching transistor T6 may be connected between a reference voltage line to which a reference voltage Vref is applied and a second capacitor CA and may be turned on in response to a third scan signal SC3. If the sixth switching transistor T6 is turned on, the reference voltage Vref may be charged to the second capacitor CA. The sixth switching transistor T6 may be formed as an N-type transistor and may be turned on when the voltage of the third scan signal SC3 is a gate high voltage.

The subpixel circuit may be driven in the order of an initialization period, a sensing period, a data writing period, an anode reset period, and an emission period.

As described above, in the subpixel circuit according to the embodiments of the present disclosure, the first switching transistor T1 may be a P-type transistor, and the second switching transistor T2 to the sixth switching transistor T6 and the driving transistor DRT may be N-type transistors.

If the first switching transistor T1 is formed of a P-type transistor, since the third node N3 may be fixed to the pixel high-potential voltage EVDD, there is an advantage that an emission current flowing to the light emitting element ED does not fluctuate due to the storage capacitor Cst. Therefore, the emission current may be stably applied to.

The P-type transistor may be a silicon transistor formed from a semiconductor such as silicon (for example, a transistor having a polysilicon channel formed using a low-temperature process referred to as LTPS or low-temperature polysilicon).

Alternatively, the N-type transistor may be formed using an oxide semiconductor (for example, a transistor having a channel formed from an oxide semiconductor such as indium, gallium, zinc oxide, IGZO or IGZTO). The oxide transistor has the characteristic of having a relatively lower leakage current than the silicon transistor.

Therefore, the driving transistor DRT constituting the subpixel circuit and at least some of the switching transistors T2 to T6 may be formed from oxide transistors. When implementing a driving transistor DRT and a switching transistor using oxide transistors, there is an effect of reducing the deterioration image quality, such as flicker, by diminishing current leakage from the driving transistor DRT.

In this case, in order to detect the flicker characteristics of the oxide transistor (e.g., DRT, T2˜T6), there may be used a test transistor that can accurately detect an interface characteristics of a buffer layer through a lower gate electrode and accurately detect an interface characteristics of a gate insulating film through an upper gate electrode.

Here, the driving transistor DRT and the switching transistor T1 to T6 that constitute the subpixel circuit may be referred to as subpixel transistors.

In this way, a subpixel SP composed of seven transistors (e.g., DRT, T1˜T6) and two storage capacitors (e.g., Cst, CA) may be referred to as a 7T2C structure.

Here, the 7T2C structure is illustrated an example among various structures of subpixel SP circuits, however, the structure and number of transistors and capacitors that constitute the subpixel SP may be changed in various ways. Meanwhile, each of the plurality of subpixels SP may have the same structure, and some of the plurality of subpixels SP may have different structures.

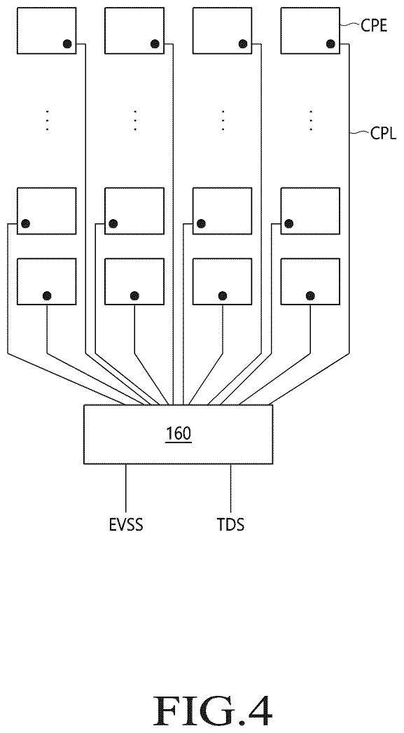

FIG. 4 illustrates a touch sensing structure of a touch display device according to embodiments of the present disclosure.

Referring to FIG. 4, a touch display device 100 according to embodiments of the present disclosure may include a plurality of cathode pattern electrodes CPE arranged in a display panel 110.

Each cathode pattern electrode CPE may be formed in a size corresponding to N×M (N, M are natural numbers greater than or equal to 2) subpixels SP.

In the touch display device 100 according to embodiments of the present disclosure, the cathode pattern electrode CPE formed in the display panel 110 may function as a touch electrode while also functioning as a common electrode.

The touch display device 100 of the present disclosure may be driven in a time-division manner during a display driving period and a touch driving period. Accordingly, the cathode pattern electrode CPE may operate as a common electrode that supplies a pixel low-potential voltage EVSS to the cathode electrode of the light emitting element ED during the display driving period and may operate as a touch electrode that supplies a touch driving signal TDS during the touch driving period.

The plurality of cathode pattern electrodes CPE may be connected to a switch circuit 160 through a cathode pattern line CPL.

The switch circuit 160 may supply a pixel low-potential voltage EVSS to the cathode pattern line CPL during the display driving period and may supply a touch driving signal TDS to the cathode pattern line CPL during the touch driving period.

That is, during the touch driving period, the cathode pattern line CPL may serve as a touch line that supplies a touch driving signal TDS to the cathode pattern electrode CPE.

The pixel low-potential voltage EVSS may be supplied from a power management circuit (not shown), and the touch driving signal TDS may be supplied from a touch circuit 150.

If the touch display device 100 according to the embodiments of the present disclosure adopts a self-capacitance sensing method, each of the plurality of cathode pattern electrodes CPE does not electrically overlap or intersect with each other. In the touch sensor structure of the self-capacitance sensing method, each of the plurality of cathode pattern electrodes CPE may be one touch node corresponding to a touch coordinate.

In this case, the touch circuit 150 may supply a touch driving signal TDS to at least one cathode pattern electrode CPE among a plurality of cathode pattern electrodes CPE through the switch circuit 160 during the touch driving period and may sense the cathode pattern electrode CPE to which the touch driving signal TDS is supplied.

Each of the plurality of cathode pattern electrodes CPE may be an electrode without an opening or may be a mesh-type electrode in which a plurality of openings are formed. In addition, each of the plurality of cathode pattern electrodes CPE may be a transparent electrode.

A sensing voltage for the cathode pattern electrode CPE supplied with the touch driving signal TDS may be a value corresponding to the capacitance or a change thereof at the cathode pattern electrode CPE supplied with the touch driving signal TDS. The capacitance at the cathode pattern electrode CPE supplied with the touch driving signal TDS may be the capacitance between the cathode pattern electrode CPE supplied with the touch driving signal TDS and a touch object.

The cathode pattern line CPL may extend from the cathode pattern electrode CPE toward the switch circuit 160 in the same direction (e.g., vertical direction). Alternatively, some of the cathode pattern lines CPL may extend in the first direction (e.g., vertical direction) and others may extend in the second direction (e.g., horizontal direction), and be connected to the switch circuit 160 along the non-display area NDA.

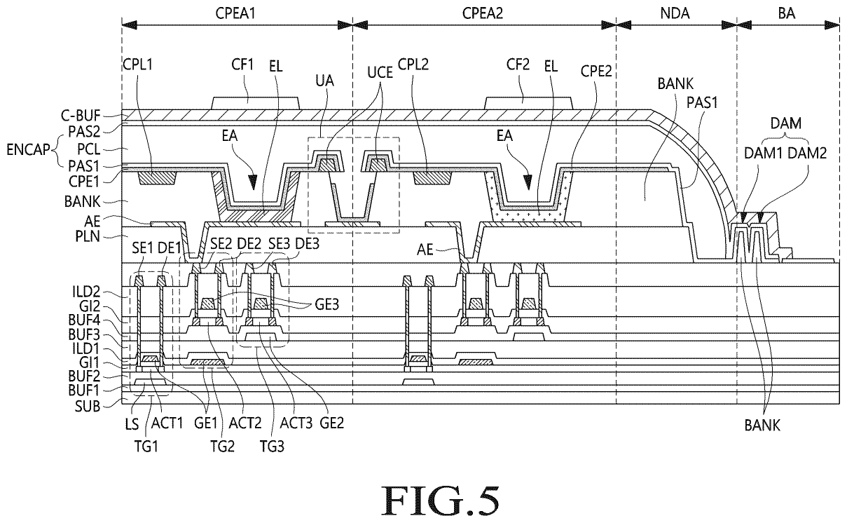

FIG. 5 illustrates an example of a cross-section of an area where a cathode pattern electrode is formed in a display device according to embodiments of the present disclosure.

Here, a first cathode pattern electrode area CPEA1 in which a first cathode pattern electrode CPE1 is formed and a second cathode pattern electrode area CPEA2 in which a second cathode pattern electrode CPE2 is formed adjacent thereto are shown as examples.

Referring to FIG. 5, the display panel 110 of the touch display device 100 according to the embodiments of the present disclosure may have a first buffer layer BUF1 formed on a substrate SUB.

A light shield layer LS for blocking light may be formed on the first buffer layer BUF1.

A second buffer layer BUF2 may be disposed to cover the light shield layer LS.

A first active layer ACT1 constituting a first transistor TG1 may be disposed on the second buffer layer BUF2.

The first transistor TG1 may include a low-temperature polysilicon transistor among the switching transistors constituting the subpixel SP. For example, the subpixel of FIG. 3 may include a first switching transistor T1.

A first gate insulating film GI1 may be disposed on the first active layer ACT1.

A first gate electrode GE1 made of a gate material may be formed on the first gate insulating film GI1. The gate material may be an opaque conductive material having low resistance, such as aluminum (Al), aluminum alloy (Al alloy), tungsten (W), copper (Cu), nickel (Ni), chromium (Cr), molybdenum (Mo), titanium (Ti), platinum (Pt), tantalum (Ta), etc. Alternatively, the gate material may be formed as a multilayer structure in which a transparent conductive material, such as indium-tin oxide (ITO) or indium-zinc oxide (IZO), and an opaque conductive material are laminated.

The first gate electrode GE1 may correspond to a gate electrode of a first transistor TG1 and may correspond to a lower gate electrode of a second transistor TG2 formed at a position spaced apart from the first transistor TG1. In addition, the first gate electrode GE1 may correspond to one electrode forming a capacitor Cst or CA.

For example, the second transistor TG2 may be a switching transistor formed of an oxide transistor in the subpixel. In the subpixel of FIG. 3, the second transistor TG2 may correspond to the second switching transistor T2 to the sixth switching transistor T6.

In this case, the second transistor TG2 may be formed with a dual gate structure including an upper gate electrode and a lower gate electrode. In this case, the first gate electrode GE1 may correspond to the lower gate electrode of the second transistor TG2.

A first interlayer insulating film ILD1 may be disposed to cover the first gate electrode GE1.

Meanwhile, a second gate electrode GE2 forming a capacitance with the first gate electrode GE1 may be formed on the first interlayer insulating film ILD1. The second gate electrode GE2 may be formed of the same gate material as the first gate electrode GE1, and a capacitor Cst and CA of the subpixel circuit may be formed by the first gate electrode GE1 and the second gate electrode GE2.

A third buffer layer BUF3 may be formed on the first interlayer insulating film ILD1.

A third gate electrode GE3 made of a gate material may be formed on the third buffer layer BUF3.

The third gate electrode GE3 may correspond to a lower gate electrode of the third transistor TG3 formed at a position spaced apart from the second transistor TG2.

For example, the third transistor TG3 may be a driving transistor DRT formed of an oxide transistor in a subpixel.

In this case, the third transistor TG3 may be formed with a dual gate structure including an upper gate electrode and a lower gate electrode. In this case, the third gate electrode GE3 may correspond to the lower gate electrode of the third transistor TG3.

In this way, the second transistor TG2 and the third transistor TG3 formed of oxide transistors may include lower gate electrodes GE1 and GE3 positioned in different layers in the vertical direction.

A fourth buffer layer BUF4 may be disposed to cover a third gate electrode GE3 on a third buffer layer BUF3.

A second active layer ACT2 forming a second transistor TG2 and a third active layer ACT3 forming a third transistor TG3 may be disposed on the fourth buffer layer BUF4.

The second active layer ACT2 may constitute an active layer of a switching transistor formed of an oxide transistor, and the third active layer ACT3 may constitute an active layer of a driving transistor formed of an oxide transistor.

A second gate insulating film GI2 may be disposed to cover the second active layer ACT2 and the third active layer ACT3.

Two or more fourth gate electrodes GE4 formed of a gate material may be formed on the second gate insulating film GI2.

The fourth gate electrode GE4 may correspond to an upper gate electrode of the second transistor TG2 and an upper gate electrode of the third transistor TG3.

A second interlayer insulating film ILD2 may be disposed to cover the fourth gate electrode GE4.

A plurality of source-drain electrode patterns may be disposed on the second interlayer insulating film ILD.

The source-drain electrode patterns may use any one of molybdenum (Mo), titanium (Ti), tantalum (Ta), tungsten (W), copper (Cu), chromium (Cr), aluminum (Al), and an alloy formed from a combination thereof.

One of the plurality of source-drain electrode patterns may correspond to a first source electrode SE1 and a first drain electrode DE1) of the first transistor TG1. In addition, another of the plurality of source-drain electrode patterns may correspond to a second source electrode SE2 and a second drain electrode DE2 of the second transistor TG2. In addition, another of the plurality of source-drain electrode patterns may correspond to a third source electrode SE3 and a third drain electrode DE3 of the third transistor TG3.

A part of the source-drain electrode pattern may be electrically connected to the second active layer ACT2 of the second transistor TG2 and the third active layer ACT3 of the third transistor TG3 through a contact hole of the second interlayer insulating film ILD2 and the second gate insulating film GI2, respectively.

In addition, another part of the source-drain electrode pattern may be electrically connected to the first active layer ACT1 of the first transistor TG1 through a contact hole of the second interlayer insulating film ILD2, the second gate insulating film GI2, the fourth buffer layer BUF4, the third buffer layer BUF3, the first interlayer insulating film ILD1, and the first gate insulating film GI1.

A planarization layer PLN may be disposed while covering the source-drain electrode pattern. The planarization layer PLN may be made of an organic insulating material such as an acrylic resin. In this case, the driving transistor DRT and some switching transistors (for example, T2 to T6) constituting the subpixel SP may be made of a dual gate structure including an upper gate electrode and a lower gate electrode to improve current characteristics in a turn-on state and secure reliability.

A light emitting element ED may be disposed on the planarization layer PLN.

The light emitting element ED may include an anode electrode AE, an emission layer EL, and a cathode pattern electrode CPE.

The anode electrode AE may be disposed on the planarization layer PLN. The anode electrode AE may be electrically connected to the second source electrode SE2 of the second transistor TG2 through a contact hole of the planarization layer PLN.

A bank BANK may be disposed to cover a portion of the anode electrode AE. A portion of the bank BANK corresponding to the emission area EA of the subpixel SP may be opened. In addition, a portion of the bank BANK may be opened between a first cathode pattern electrode area CPEA1 and a second cathode pattern electrode area CPEA2 to form an undercut area UA that electrically insulates a first cathode pattern electrode area CPEA1 and a second cathode pattern electrode area CPEA2.

A portion of the anode electrode AE may be exposed to the emission area EA where the bank BANK is opened.

The emission layer EL may be located on the side of the bank BANK and the emission area EA where the bank BANK is opened. The emission layer EL may include an organic film. In the emission area EA where the bank BANK is open, the emission layer EL may be in contact with the anode electrode AE.

Alternatively, the emission layer EL may not be formed in the undercut area UA that insulates the cathode pattern electrode area CPEA1 and CPEA2.

In some areas of the upper portion of the bank BANK, a cathode pattern line CPL1 and CPL2 electrically connected to the cathode pattern electrode CPE1 and CPE2 may be formed.

The cathode pattern line CPL1 and CPL2 may be formed as a third source-drain electrode pattern in a recessed area where some areas of the upper portion of the bank BANK are etched.

If the cathode pattern line CPL1 and CPL2 is formed in a recessed area on the bank BANK, a distance from the cathode pattern electrodes CPE1 and CPE2 can be shortened, thereby reducing the resistance.

Meanwhile, in the process of forming the cathode pattern lines CPL1 and CPL2, an undercut structure may be formed in the undercut area UA to insulate the first cathode pattern electrode CPE1 and the second cathode pattern electrode CPE2.

The undercut structure may include a bank groove in which the bank BANK is etched in the undercut area UA, and an undercut electrode UCE protruding in the direction of the bank groove in an upper edge of the bank groove.

The undercut electrode UCE may be formed with the same third source-drain electrode pattern as the cathode pattern lines CPL1 and CPL2.

The first cathode pattern electrode CPE1 and the second cathode pattern electrode CPE2 may be electrically insulated by the undercut structure.

The first cathode pattern electrode CPE1 may serve as a cathode electrode of the first cathode pattern electrode area CPEA1, and the second cathode pattern electrode CPE2 may serve as a cathode electrode of the second cathode pattern electrode area CPEA2.

An encapsulation layer ENCAP can be disposed to cover the cathode pattern electrodes CPE1 and CPE2.

The encapsulation layer ENCAP may block external moisture or oxygen from penetrating into the light emitting element ED that is vulnerable to external moisture or oxygen. The encapsulation layer ENCAP may be formed as a single layer, but may also be formed as a plurality of laminated structures (e.g., PAS1, PCL, PAS2).

For example, if the encapsulation layer ENCAP is composed of a plurality of laminated structures, the encapsulation layer ENCAP may include one or more inorganic encapsulation layers PAS1 and PAS2, and one or more organic encapsulation layers PCL. For example, the encapsulation layer ENCAP may be laminated or stacked in the order of a first inorganic encapsulation layer PAS1, an organic encapsulation layer PCL, and a second inorganic encapsulation layer PAS2, but the embodiments of the present disclosure are not limited thereto.

The organic encapsulation layer PCL may further include at least one organic encapsulation layer or at least one inorganic encapsulation layer, but the embodiments of the present disclosure are not limited thereto.

The first inorganic encapsulating layer PAS1 may be formed on a substrate SUB on which a second electrode E2 corresponding to a cathode electrode is formed so as to be most adjacent to the light emitting element ED. The first inorganic encapsulating layer PAS1 may be formed of an inorganic insulating material capable of low-temperature deposition, such as silicon nitride (SiNx), silicon oxide (SiOx), silicon oxynitride (SiON), or aluminum oxide (Al2O3), but the embodiments of the present disclosure are not limited thereto. Since the first inorganic encapsulating layer PAS1 is deposited in a low-temperature atmosphere, the first inorganic encapsulating layer PAS1 may prevent the emission layer EL including an organic material vulnerable to a high-temperature atmosphere from being damaged during the deposition process.

The organic encapsulation layer PCL may be formed with a smaller area than the first inorganic encapsulation layer PAS1, and in this case, the organic encapsulation layer PCL may be formed to expose both ends of the first inorganic encapsulation layer PAS1. The organic encapsulation layer PCL may act as a buffer to relieve stress between each layer due to bending of the touch display device and may act to enhance flattening performance. The organic encapsulation layer PCL may be formed of an organic insulating material, such as, for example, an acrylic resin, an epoxy resin, a polyimide, polyethylene, or silicon oxycarbon (SiOC), but the embodiments of the present disclosure are not limited thereto.

If the organic encapsulation layer PCL is formed by an inkjet method, one or more dams DAM may be formed in a dam area corresponding to a boundary area between a non-display area NDA and a display area DA or a portion of an area within the non-display area NDA.

For example, the dam area may be located between the bending area BA or the pad area where multiple pads are formed and the display area DA. The dam area may have a first dam DAM1 adjacent to the display area DA and a second dam DAM2 adjacent to the pad area.

One or more dams DAM disposed in the dam area can prevent the liquid-type organic encapsulating layer PCL from collapsing in the direction of the non-display area and encroaching on the pad area during a process of forming the liquid-type organic encapsulating layer PCL in the display area DA.

The first dam DAM1 or the second dam DAM2 may be formed in a single-layer or multi-layer structure. For example, the first dam DAM1 or the second dam DAM2 may be formed simultaneously with the same material as at least one of the bank BANK and the spacer. Accordingly, a dam structure may be formed without additional mask processes and increased costs. For example, a spacer may be disposed on a bank BANK, In addition, the first dam DAM1 or the second dam DAM2 may be formed by a structure in which a first inorganic encapsulation layer PAS1 and a second inorganic encapsulation layer PAS2 are laminated on a bank BANK. An organic encapsulation layer PCL including an organic material may be positioned on an inner surface of the first dam DAM1 or on at least a portion of the first dam DAM1 and the second dam DAM2.

The second inorganic encapsulation layer PAS2 may be formed on a substrate SUB on which the organic encapsulation layer PCL is formed so as to cover the upper surface and side surface of each of the organic encapsulation layer PCL and the first inorganic encapsulation layer PAS1. The second inorganic encapsulating layer PAS2 can minimize or block external moisture or oxygen from penetrating into the first inorganic encapsulating layer PAS1 and the organic encapsulating layer PCL. The second inorganic encapsulating layer PAS2 may be formed of an inorganic insulating material, such as silicon nitride (SiNx), silicon oxide (SiOx), silicon oxynitride (SiON), or aluminum oxide (Al2O3), but the embodiments of the present disclosure are not limited thereto.

In addition, the touch display device 100 according to the embodiments of the present disclosure may have a structure in which a color filter layer is disposed on the encapsulating layer ENCAP.

The display panel 110 may include a color filter buffer layer C-BUF formed on the encapsulating layer ENCAP, and a color filter layer disposed on the color filter buffer layer C-BUF. The structure in which the color filter layer is disposed on the encapsulation layer ENCAP may be also referred to as color-filter-on-encapsulation layer (COE) structure.

The color filter layer in which the color filter CF1 and CF2 is formed may be disposed on an upper side of the emission area EA within the display area DA. The color filter layer may further include a black matrix (not shown) positioned at the boundary area of the color filter CF1 and CF2.

Within the display area DA, light flowing into the front may be blocked by the black matrix, and light flowing through the color filter CF1 and CF2 may be blocked by the anode electrode AE.

The black matrix may serve as a boundary between the emission areas EA within the display area DA and may serve as a partition that divides each subpixel area. In addition, the black matrix may distinguish the emission areas EA of the subpixels SP from each other and prevent color mixing of the subpixels SP. Accordingly, the contrast ratio may be improved and the display performance may be enhanced.

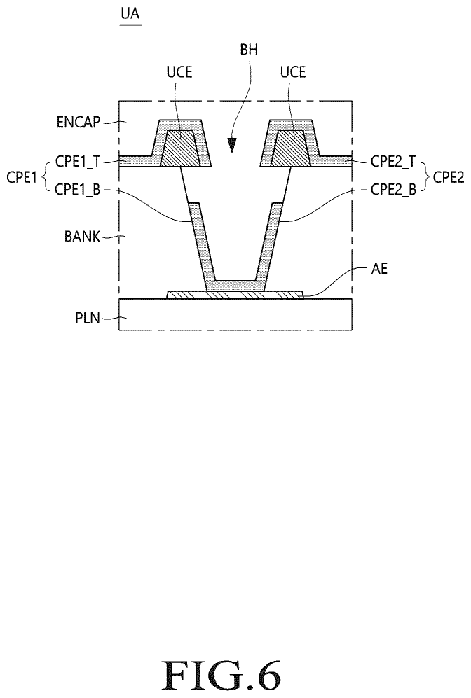

FIG. 6 is a cross-sectional view illustrating an undercut area of FIG. 5 in the touch display device according to embodiments of the present disclosure.

Referring to FIG. 6, in the touch display device 100 according to embodiments of the present disclosure, a first cathode pattern electrode CPE1 and a second cathode pattern electrode CPE2 may be divided or separated, by an undercut electrode UCE, into an upper cathode pattern electrode CPE1_T and CPE2_T located above the bank BANK and a lower cathode pattern electrode CPE1_B and CPE2_B located inside the bank groove BH.

To this end, a process can be performed such that two undercut electrodes UCE are formed to be spaced apart at a certain interval on the bank BANK, and a part of the lower part of the undercut electrode UCE is etched in the process of etching the bank BANK located between the two undercut electrodes UCE. As a result, there may be separated into an upper cathode pattern electrode CPE1_T and CPE2_T located on the upper side of the bank BANK and a lower cathode pattern electrode CPE1_B and CPE2_B located inside the bank groove BH.

In this case, the upper cathode pattern electrodes CPE1_T and CPE2_T located on the upper side of the bank BANK and the lower cathode pattern electrodes CPE1_B and CPE2_B located inside the bank groove BH may be formed of the same cathode electrode material. For example, the cathode electrode material may include a transparent conductive material.

That is, the touch display device 100 of the present disclosure may have an undercut shape in which the cathode pattern electrode CPE is separated or disconnected in the bank groove BH by the undercut electrode UCE in the undercut area UA.

Therefore, in the undercut area UA, the first cathode pattern electrode CPE1 may be divided into a first upper cathode pattern electrode CPE1_T and a first lower cathode pattern electrode CPE1_B located inside the bank groove BH that are electrically separated from each other. In addition, in the undercut area UA, the second cathode pattern electrode CPE2 may be divided into a second upper cathode pattern electrode CPE2_T and a second lower cathode pattern electrode CPE2_B located inside the bank groove BH that are electrically separated from each other.

In this case, the cathode pattern line CPL and the undercut electrode UCE may be formed by the same third source-drain electrode, thereby simplifying the process of forming the cathode pattern electrode CPE.

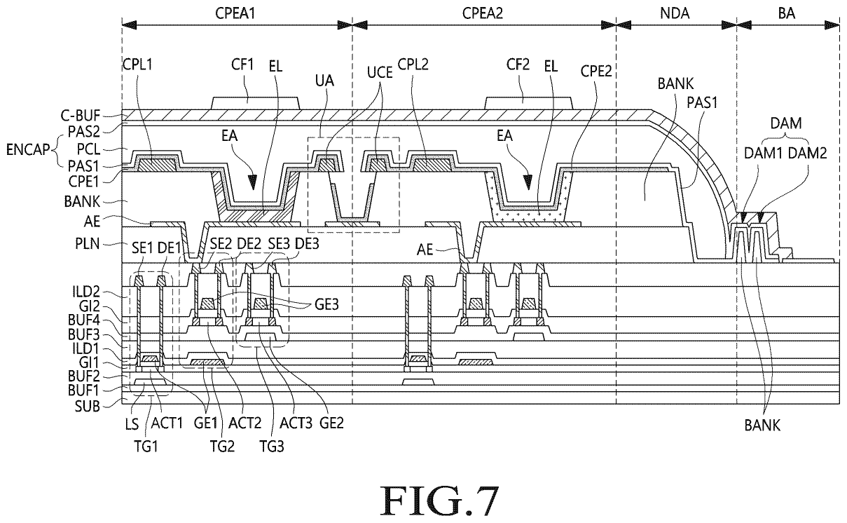

FIG. 7 illustrates a cross-section of an area where a cathode pattern electrode is formed in a display device according to another embodiment of the present disclosure.

Referring to FIG. 7, in a touch display device 100 according to embodiments of the present disclosure, the cathode pattern lines CPL1 and CPL2 connected to the cathode pattern electrodes CPE1 and CPE2 and the undercut electrode UCE may be formed using the same material and through the same process.

Here, it will be described a configuration different from FIG. 4.

The cathode pattern line CPL1 and CPL2 electrically connected to the cathode pattern electrodes CPE1 and CPE2 may be formed in some area on the bank BANK.

The cathode pattern lines CPL1 and CPL2 may be formed using the same material and through the same process as the undercut electrode UCE on the bank BANK.

If the cathode pattern lines CPL1 and CPL2 are formed in the same process as the undercut electrode UCE on the upper side of the bank BANK, it is possible to simplify the process of forming the cathode pattern electrodes CPE1 and CPE2 and the cathode pattern lines CPL1 and CPL2.

Therefore, in the process of forming the cathode pattern line CPL, an undercut structure for insulating the first cathode pattern electrode CPE1 and the second cathode pattern electrode CPE2 may be formed in the undercut area UA.

The undercut structure may include a bank groove BH in which a portion of the bank BANK is etched in the undercut area UA and an undercut electrode UCE protruding in the direction of the bank groove in the upper edge of the bank groove BH.

The undercut electrode UCE may be formed with a third source-drain electrode pattern identical to the cathode pattern line CPL.

The first cathode pattern electrode CPE1 and the second cathode pattern electrode CPE2 may be electrically insulated by the undercut structure.

The first cathode pattern electrode CPE1 may serve as a cathode electrode of the first cathode pattern electrode area CPEA1, and the second cathode pattern electrode CPE2 may serve as a cathode electrode of the second cathode pattern electrode area CPEA2.

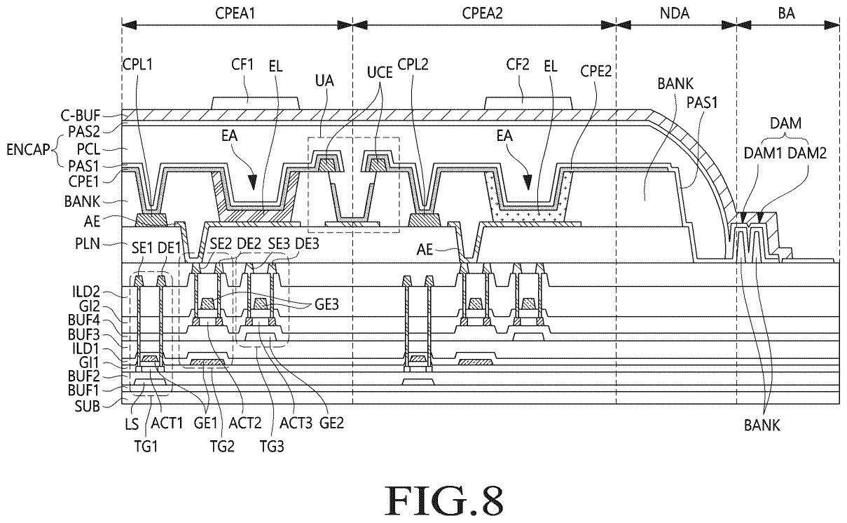

FIG. 8 illustrates an example of a cross-section of an area where a cathode pattern electrode is formed in a display device according to another embodiment of the present disclosure.

Referring to FIG. 8, in the touch display device 100 according to the embodiments of the present disclosure, the cathode pattern lines CPL1 and CPL2 connected to the cathode pattern electrodes CPE1 and CPE2 and the undercut electrode UCE may be formed using the same material and through the same process.

In this case, the cathode pattern lines CPL1 and CPL2 electrically connected to the cathode pattern electrodes CPE1 and CPE2 may be formed by etching a portion of the bank BANK to be positioned on top of the planarization layer PLN.

In this case, the cathode pattern lines CPL1 and CPL2 may be positioned on a different layer from the cathode pattern electrodes CPE1 and CPE2. As a result, it is possible to prevent a phenomenon of the cathode pattern lines CPL1 and CPL2 electrically contacting other cathode pattern electrodes during the extension process.

That is, even if the cathode pattern lines CPL1 and CPL2 extend horizontally within the display panel 110, since they are spaced apart from the cathode pattern electrode CPE by a specific height, it is possible to suppress a phenomenon of electrical contact with other cathode pattern electrodes.

Meanwhile, the cathode pattern lines CPL1 and CPL2 may be formed of the same material as the undercut electrode UCE formed on the upper part of the bank BANK.

However, in this case, a process of etching a part of the bank BANK may be added to form the cathode pattern lines CPL1 and CPL2.

Similarly, in the process of forming the cathode pattern lines CPL, an undercut structure may be formed in the undercut area UA to insulate the first cathode pattern electrode CPE1 and the second cathode pattern electrode CPE2.

The undercut structure may include a bank groove BH in which a portion of the bank BANK is etched in an undercut area UA and an undercut electrode UCE protruding in the direction of the bank groove in an upper edge of the bank groove BH.

The undercut electrode UCE may be formed with a third source-drain electrode pattern identical to the cathode pattern line CPL.

A first cathode pattern electrode CPE1 and a second cathode pattern electrode CPE2 may be electrically insulated by the undercut structure.

The first cathode pattern electrode CPE1 may serve as a cathode electrode of the first cathode pattern electrode area CPEA1, and the second cathode pattern electrode CPE2 may serve as a cathode electrode of the second cathode pattern electrode area CPEA2.

Meanwhile, in the touch display device 100 of the present disclosure, an undercut structure separating adjacent cathode pattern electrodes CPE1 and CPE2 may be formed on the lower portion of the bank BANK and the upper portion of the planarization layer PLN.

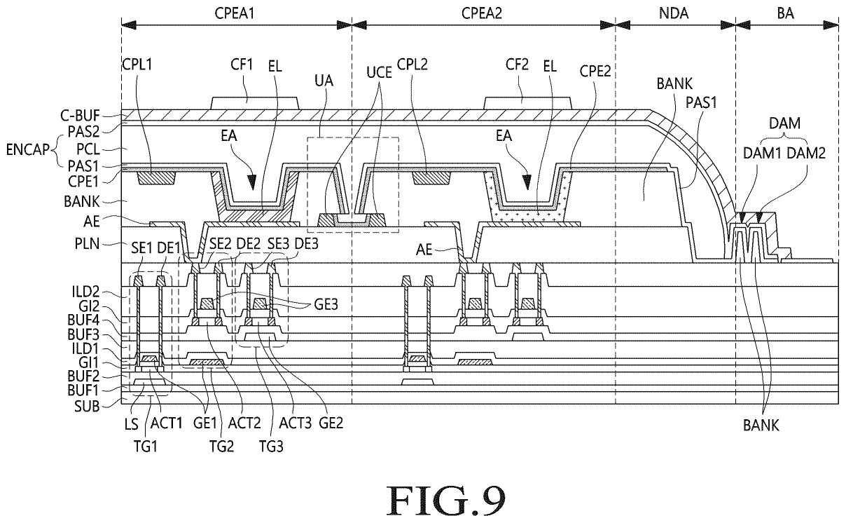

FIG. 9 illustrates an example of a case in which a cathode pattern electrode is separated through an undercut structure at the bottom of a bank in a display device according to other embodiments of the present disclosure.

Here, a first cathode pattern electrode area CPEA1 in which a first cathode pattern electrode CPE1 is formed and a second cathode pattern electrode area CPEA2 in which a second cathode pattern electrode CPE2 is formed adjacent thereto are illustrated as examples.

Hereinafter, parts overlapping with FIG. 5 will be omitted, and descriptions will be made focusing on different parts.

Referring to FIG. 9, a display panel 110 of a touch display device 100 according to embodiments of the present disclosure may include a substrate SUB, a driving transistor DRT, a planarization layer PLN, a light emitting element ED, and an encapsulation layer ENCAP.

The driving transistor DRT may be disposed on the upper portion of the substrate SUB for each subpixel constituting the cathode pattern electrode area CPEA1 and CPEA2.

The planarization layer PLN may be disposed on the upper portion of the driving transistor DRT.

An undercut structure separating the cathode pattern electrodes CPE1 and CPE2 and a light emitting element ED may be formed on the planarization layer PLN.

The light emitting element ED may include an anode electrode AE, an emission layer EL, and a cathode pattern electrode CPE.

The anode electrode AE may be disposed on a second planarization layer PLN2. The anode electrode AE may be electrically connected to a second source-drain electrode pattern SD2 through a contact hole of the second planarization layer PLN2.

Meanwhile, the emission layer EL may not be formed in the undercut area UA separating the cathode pattern electrode areas CPEA1 and CPEA2.

In this case, two undercut electrodes UCE may be disposed to face each other at a specific interval on the top of the planarization layer PLN of the undercut area UA to form an undercut structure.

A bank BANK may be disposed to cover the anode electrode AE and the undercut electrode UCE.

A part of the bank BANK corresponding to the emission area EA and the undercut area UA may be opened.

In this case, the bank BANK covering the undercut electrode UCE may be formed to protrude into the space between the undercut electrodes UCE. As a result, the bank BANK located on the upper side of the undercut electrode UCE and the undercut electrode UCE may form an undercut structure.

In addition, a part of the anode electrode AE may be exposed to the emission area EA where the bank BANK is opened.

The emission layer EL may be located on the side of the bank BANK and in the emission area EA where the bank BANK is opened. The emission layer EL may include an organic film. In the emission area EA where the bank BANK is opened, the emission layer EL may be in contact with the anode electrode AE.

In addition, a cathode pattern line CPL1 and CPL2 electrically connected to the cathode pattern electrode CPE1 and CPE2 may be formed on the upper surface of the bank BANK.

The cathode pattern line CPL1 and CPL2 may be formed as a third source-drain electrode pattern in a recessed area where a portion of the upper portion of the bank BANK is etched.

If the cathode pattern lines CPL1 and CPL2 are formed in the recessed area of the upper portion of the bank BANK, a distance from the cathode pattern electrodes CPE1 and CPE2 may be shortened, thereby reducing the resistance.

The cathode pattern lines CPL1 and CPL2 and the undercut electrode UCE may be formed as the same third source-drain electrode pattern.

The first cathode pattern electrode CPE1 may serve as a cathode electrode of the first cathode pattern electrode area CPEA1, and the second cathode pattern electrode CPE2 may serve as a cathode electrode of the second cathode pattern electrode area CPEA2.

An encapsulation layer ENCAP may be disposed to cover the cathode pattern electrodes CPE1 and CPE2.

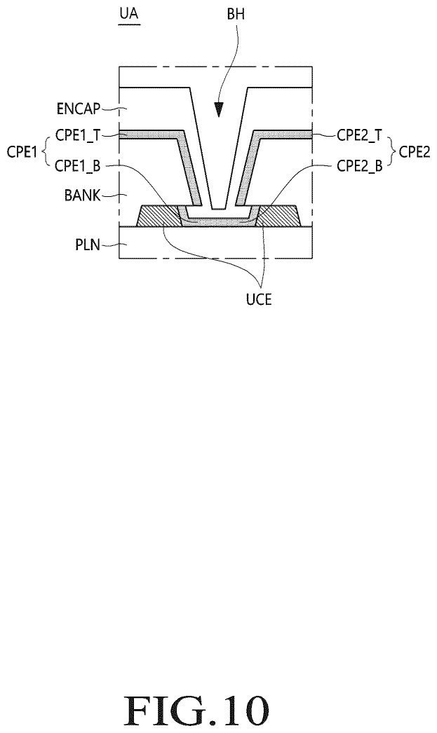

FIG. 10 is a cross-sectional view illustrating an undercut area of FIG. 8 in a touch display device according to embodiments of the present disclosure.

Referring to FIG. 10, in the touch display device 100 according to the embodiments of the present disclosure, the first cathode pattern electrode CPE1 and the second cathode pattern electrode CPE2 may be separated into upper cathode pattern electrodes CPE1_T and CPE2_T positioned on the upper side of the bank BANK and lower cathode pattern electrodes CPE1_B and CPE2_B positioned inside the bank groove BH by an undercut electrode UCE located on the upper side of the planarization layer PLN.

To this end, a process may be performed such that two undercut electrodes UCE spaced apart at a specific interval on the bank BANK are formed, and a part of the lower side of the undercut electrode UCE is etched in the process of etching the bank BANK located between the two undercut electrodes UCE. As a result, there may be separated into an upper cathode pattern electrode CPE1_T and CPE2 T located on the upper side of the bank BANK and a lower cathode pattern electrode CPE1_B and CPE2_B located on the inside of the bank groove BH.

That is, there may be formed an undercut structure in which the undercut electrode UCE is introduced into the inside of the bank BANK from the outside of the bank groove BH, and the bank BANK located on the upper side of the undercut electrode UCE protrudes toward the bank groove BH.

As a result, the cathode pattern electrode CPE formed on the upper side of the bank BANK may be electrically separated into a first cathode pattern electrode CPE1 and a second cathode pattern electrode CPE2 in the bank groove BH.

In this case, the upper cathode pattern electrode CPE1_T and CPE2_T located on the upper side of the bank BANK and the lower cathode pattern electrode CPE1_B and CPE2_B located inside the bank groove BH may formed of the same cathode electrode material. For example, the cathode electrode material may include a transparent conductive material.

That is, the touch display device 100 of the present disclosure may have an undercut shape in which the cathode pattern electrode CPE is separated in the bank groove BH by the undercut electrode UCE in the undercut area UA.

Therefore, in the undercut area UA, the first cathode pattern electrode CPE1 may be electrically separated into the first upper cathode pattern electrode CPE1_T and the first lower cathode pattern electrode CPE1_B located inside the bank groove BH. In addition, in the undercut area UA, the second cathode pattern electrode CPE2 may be electrically separated into the second upper cathode pattern electrode CPE2_T and the second lower cathode pattern electrode CPE2_B located inside the bank groove BH.

In this case, the process of forming the cathode pattern electrode CPE may be simplified by forming the cathode pattern line CPL and the undercut electrode UCE as the same third source-drain electrode.

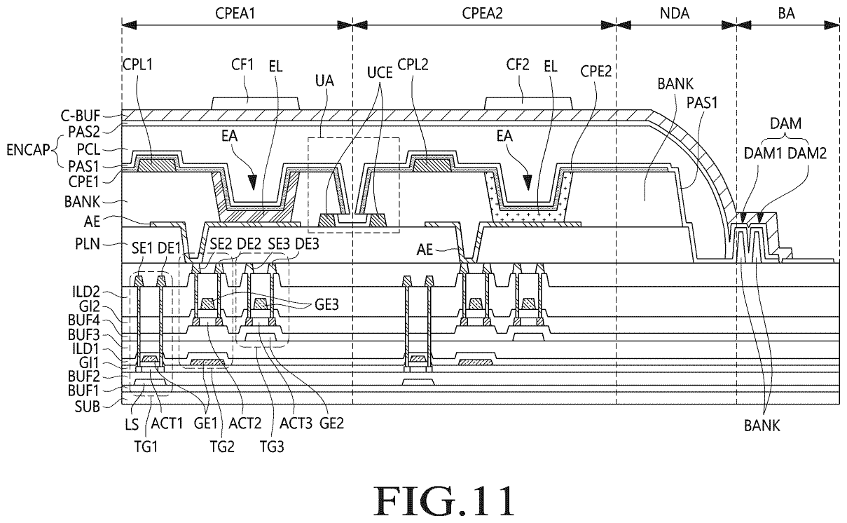

FIG. 11 illustrates a cross-section of a case where the cathode pattern electrode is separated through an undercut structure at the lower portion of the bank in a display device according to another embodiment of the present disclosure.

Referring to FIG. 11, in the touch display device 100 according to the embodiments of the present disclosure, the cathode pattern lines CPL1 and CPL2 connected to the cathode pattern electrodes CPE1 and CPE2 and the undercut electrode UCE may be formed using the same material.

Here, it will be described a configuration different from FIG. 9.

The cathode pattern lines CPL1 and CPL2 electrically connected to the cathode pattern electrodes CPE1 and CPE2 may be formed in some area of the upper portion of the bank BANK.

The cathode pattern lines CPL1 and CPL2 may be formed using the same material as the undercut electrode UCE at the lower portion of the bank BANK.

In this case, the first cathode pattern electrode CPE1 and the second cathode pattern electrode CPE2 may be separated or divided into an upper cathode pattern electrodes CPE1_T and CPE2_T located on the upper side of the bank BANK and a lower cathode pattern electrodes CPE1_B and CPE2_B located inside the bank groove BH by an undercut electrode UCE located on the planarization layer PLN.

That is, there may be formed an undercut structure in which the undercut electrode UCE may be introduced into the inside of the bank BANK from the outside of the bank groove BH, and the bank BANK located on the upper side of the undercut electrode UCE protrudes in the direction of the bank groove BH.

As a result, the cathode pattern electrode CPE formed on the bank BANK may be electrically separated into the first cathode pattern electrode CPE1 and the second cathode pattern electrode CPE2 in the bank groove BH.

The undercut electrode UCE may be formed with the same third source-drain electrode pattern as the cathode pattern line CPL.

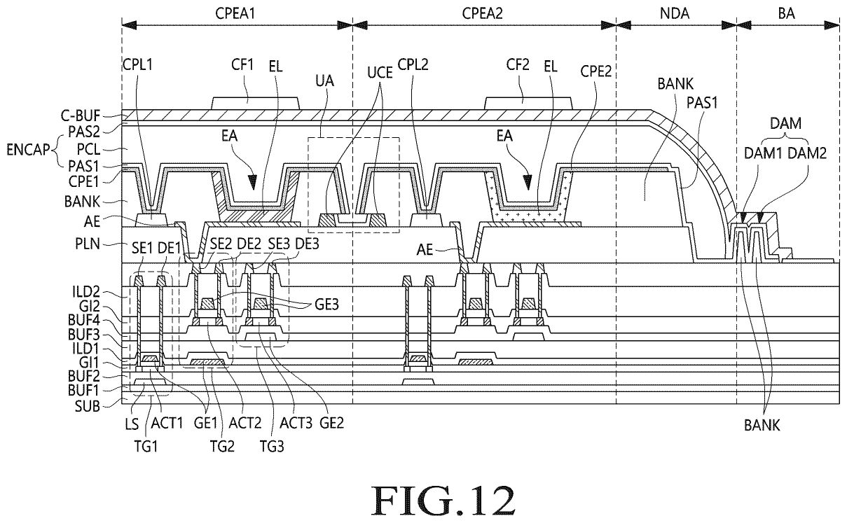

FIG. 12 illustrates a cross-section of a display device according to another embodiment of the present disclosure in which an undercut structure and a cathode pattern line are formed on the lower side of the bank.

Referring to FIG. 12, in the touch display device 100 according to the embodiments of the present disclosure, the cathode pattern lines CPL1 and CPL2 connected to the cathode pattern electrodes CPE1 and CPE2 and the undercut electrode UCE may be formed with the same third source-drain electrode pattern.

In this case, the cathode pattern lines CPL1 and CPL2 electrically connected to the cathode pattern electrodes CPE1 and CPE2 may be formed by etching a portion of the bank BANK to be located on the planarization layer PLN.

In this case, the cathode pattern lines CPL1 and CPL2 may be located on a different layer from the cathode pattern electrodes CPE1 and CPE2. As a result, there may be prevented a phenomenon of the cathode pattern lines CPL1 and CPL2 electrically contacting other cathode pattern electrodes during the extension process.

That is, even if the cathode pattern lines CPL1 and CPL2 extend horizontally within the display panel 110, since they are separated from the cathode pattern electrodes CPE by a specific height, there may be suppressed a phenomenon of electrically contacting other cathode pattern electrodes.

Meanwhile, the cathode pattern lines CPL1 and CPL2 may be formed of the same material as the undercut electrode UCE.

In addition, an undercut structure may be formed in the undercut area UA to insulate the first cathode pattern electrode CPE1 and the second cathode pattern electrode CPE2.

The first cathode pattern electrode CPE1 and the second cathode pattern electrode CPE2 may be separated into an upper cathode pattern electrode CPE1_T and CPE2_T located on the bank BANK and a lower cathode pattern electrode CPE1_B and CPE2_B located inside the bank groove BH by the undercut electrode UCE located on the planarization layer PLN.

That is, there may be formed an undercut structure in which the undercut electrode UCE is introduced into the inside of the bank BANK from the outside of the bank groove BH, and the bank BANK located on the undercut electrode UCE protrudes toward the bank groove BH.

As a result, the cathode pattern electrode CPE formed above the bank BANK may be electrically separated into a first cathode pattern electrode CPE1 and a second cathode pattern electrode CPE2 in the bank groove BH.

The undercut electrode UCE may be formed as a third source-drain electrode pattern that is the same as the cathode pattern line CPL.

The touch display device 100 of the present disclosure may be driven in a time-division manner during a display driving period and a touch driving period. Accordingly, the cathode pattern electrode CPE may operate as a common electrode that supplies a pixel low-potential voltage EVSS to the cathode electrode of the light emitting element ED during the display driving period and may operate as a touch electrode that supplies a touch driving signal TDS during the touch driving period.

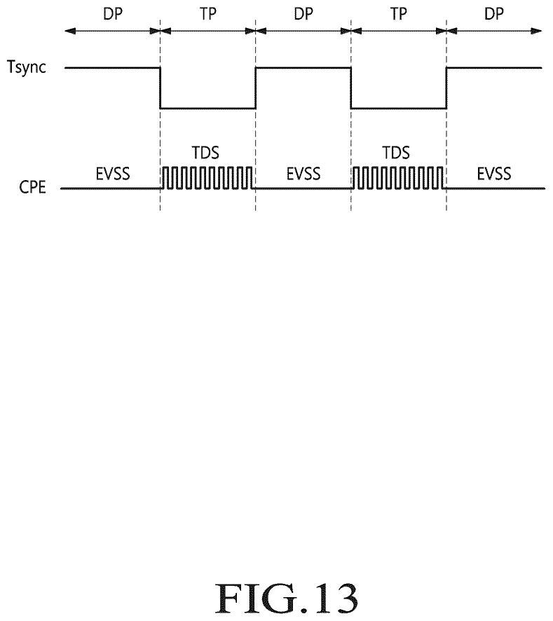

FIG. 13 illustrates an example of a signal applied to the cathode pattern electrode in time-division driving in a touch display device according to embodiments of the present disclosure.

Referring to FIG. 13, the touch display device 100 according to embodiments of the present disclosure may perform a display driving period DP and a touch driving period TP at different time periods. That is, the touch display device 100 according to embodiments of the present disclosure may perform the display driving period DP and the touch driving period TP by a time-division method.

The touch display device 100 according to the embodiments of the present disclosure may use a touch synchronization signal Tsync to distinguish between the display driving period DP and the touch driving period TP.

For example, in the touch synchronization signal Tsync, a first level (e.g., a high level or a low level) may indicate a display driving period DP, and a second level (e.g., a low level or a high level) may indicate a touch driving period TP.

During the touch driving period TP, all or part of the plurality of cathode pattern electrodes CPE may be supplied with a touch driving signal TDS. During the display driving period DP, the plurality of cathode pattern electrodes CPE may be supplied with a pixel low-potential voltage EVSS. That is, the cathode pattern electrodes CPE may be supplied with a pixel low-potential voltage EVSS for display driving operation during the display driving period DP, and may be supplied with a touch driving signal TDS during the touch driving period TP.

The touch driving signal TDS applied to the cathode pattern electrodes CPE during the touch driving period TP may be a signal of a constant level or may be an alternating current (AC) signal having a variable voltage level. In the case that the touch driving signal TDS is an AC signal, the touch driving signal TDS may also be referred to as a modulation signal or a pulse signal.

While a touch driving signal TDS is applied to the cathode pattern electrode CPE, a direct current (DC) level signal may be applied to other electrodes surrounding the cathode pattern electrode CPE.

Meanwhile, while a touch driving signal TDS is applied to the cathode pattern electrode CPE during the touch driving period TP, the cathode pattern electrode CPE may form a parasitic capacitance with other electrodes. This parasitic capacitance may reduce touch sensitivity.

Therefore, while the touch display device 100 applies a touch driving signal TDS to the cathode pattern electrode CPE, a load-free driving signal may be applied to other electrodes surrounding the cathode pattern electrode CPE.

The load-free driving signal may be a touch driving signal TDS or may be a signal whose at least one of frequency, phase, voltage polarity and amplitude correspond to that of the touch driving signal.

Other electrodes around the cathode pattern electrode CPE may be a data line DL, a gate line GL, an anode electrode AE, or another cathode pattern electrode, and may also be all electrodes or signal wirings around the cathode pattern electrode CPE.

Meanwhile, in the touch display device 100 of the present disclosure, the cathode pattern line CPL connected to the cathode pattern electrode CPE may extend in different directions depending on the position of the cathode pattern electrode CPE.

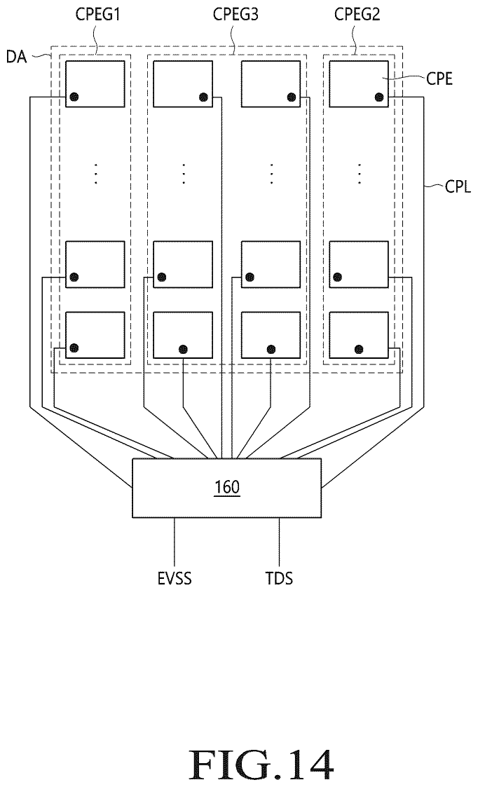

FIG. 14 schematically illustrates a touch sensing structure having different extension directions of the cathode pattern line in a touch display device according to embodiments of the present disclosure.

Referring to FIG. 14, in a touch display device 100 according to embodiments of the present disclosure, cathode pattern electrodes arranged in a display area DA of a display panel 110 may be classified into a plurality of cathode pattern electrode groups CPEG1, CPEG2 and CPEG3 depending on their positions.

For example, a plurality of cathode pattern electrodes located adjacent to the left non-display area of the display panel 110 may be classified as a first cathode pattern electrode group CPEG1, and a plurality of cathode pattern electrodes positioned adjacent to the right non-display area of the display panel 110 may be classified as a second cathode pattern electrode group CPEG2. In addition, a plurality of cathode pattern electrodes positioned between the first cathode pattern electrode group CPEG1 and the second cathode pattern electrode group CPEG2 may be classified as a third cathode pattern electrode group CPEG3.

In this case, if a switch circuit 160 supplying the pixel low-potential voltage EVSS or the touch driving signal TDS through a plurality of cathode pattern lines CPL is located at the bottom of the display panel 110, the first cathode pattern electrode group CPEG1 may be connected to a cathode pattern line CPL extending along the left non-display area, the second cathode pattern electrode group CPEG2 may be connected to a cathode pattern line CPL extending along the right non-display area, and the third cathode pattern electrode group CPEG3 may be connected to a cathode pattern line CPL extending along the display area DA.

In this way, the positions of the extension of the plurality of cathode pattern lines CPL may be changed depending on the arrangement of the cathode pattern electrode groups CPEG1, CPEG2 and CPEG3, it is possible to reduce an electrical contact or a defect between the cathode pattern lines CPL.

The switch circuit 160 may supply a pixel low-potential voltage EVSS to the cathode pattern line CPL during the display driving period and may supply a touch driving signal TDS to the cathode pattern line CPL during the touch driving period.

The pixel low-potential voltage EVSS may be supplied from a power management circuit (not shown), and the touch driving signal TDS may be supplied from the touch circuit 150.

The touch display device and the display panel according to the embodiments of the present disclosure may be described as follows.

A touch display panel according to the embodiments of the present disclosure may include a substrate, a driving transistor formed on the substrate, and a light emitting element corresponding to the driving transistor on the driving transistor. The light emitting element may include an anode electrode formed in an emission area in which a portion of a bank is open, an emission layer contacting the anode electrode in the emission area, and a cathode pattern electrode formed to cover N×M (N, M are natural numbers greater than or equal to 2) light emitting elements along an upper surface of the bank, and contacting the emission layer in the emission area. The cathode pattern electrode may be electrically separated from an adjacent cathode pattern electrode by an undercut electrode formed in an undercut area of the bank, and an electrical signal may be applied through a cathode pattern line electrically connected to the cathode pattern electrode.

The undercut area may include a bank groove in which a portion of the bank is open, and a pair of undercut electrodes protruding inwardly in an upper portion of the bank groove.

The cathode pattern line may be formed in a recessed area on the bank and may be in electrical contact with the cathode pattern electrode located thereon.

The cathode pattern line and the undercut electrode may be formed as a source-drain electrode pattern that constitutes a source electrode and a drain electrode of the driving transistor.

The cathode pattern line may be supplied with a pixel low-potential voltage during a display driving period and may be supplied with a touch driving signal during a touch driving period.

The cathode pattern electrode may include a first cathode pattern electrode group adjacent to a first non-display area, a second cathode pattern electrode group adjacent to a second non-display area opposite to the first non-display area, and a third cathode pattern electrode group located between the first cathode pattern electrode group and the second cathode pattern electrode group. The cathode pattern lines may include a first cathode pattern line extending along the first non-display area and connected to the first cathode pattern electrode group, a second cathode pattern line extending along the second non-display area and connected to the second cathode pattern electrode group, and a third cathode pattern line extending along a display area and connected to the third cathode pattern electrode group.

The cathode pattern line may be formed in a protruding shape on the bank and may be in electrical contact with the cathode pattern electrode located thereon.

The cathode pattern line may be formed on a planarization layer within a groove in which a portion of the bank is etched and may be in electrical contact with the cathode pattern electrode located thereon.

The undercut area may include a bank groove in which a portion of the bank is open, and a pair of undercut electrodes introduced into the inside of the bank in a lower portion of the bank groove.

The cathode pattern line may be formed in a recessed area on the bank and may in electrical contact with the cathode pattern electrode thereon.

The cathode pattern line may be formed in a protruding shape on the bank and may be in electrical contact with the cathode pattern electrode thereon.

The cathode pattern line may be formed on a planarization layer within a groove in which a portion of the bank is etched and may be in electrical contact with the cathode pattern electrode located thereon.

A touch display device according to the embodiments of the present disclosure may include a display panel including a substrate, a driving transistor formed on the substrate, and a light emitting element corresponding to the driving transistor on the driving transistor, a driving circuit for supplying a driving signal to the display panel, a switch circuit for supplying a pixel low-potential voltage or a touch driving signal to the display panel, and a timing controller for controlling the driving circuit and the switch circuit. The light emitting element may include an anode electrode formed in an emission area in which a portion of a bank is open, an emission layer contacting the anode electrode in the emission area, and a cathode pattern electrode formed to cover N×M (N, M are natural numbers greater than or equal to 2) light emitting elements along an upper surface of the bank, and contacting the emission layer in the emission area. The cathode pattern electrode may be electrically separated from an adjacent cathode pattern electrode by an undercut electrode formed in an undercut area of the bank, and the pixel low-potential voltage or the touch driving signal may be applied to the cathode pattern electrode through a cathode pattern line.

The above description has been presented to enable any person skilled in the art to make and use the technical idea of the present invention and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.

1. A touch display panel comprising:
a substrate;
a driving transistor on the substrate; and
a light emitting element connected to the driving transistor, the light emitting element over the driving transistor,
wherein the light emitting element comprises:
an anode electrode in an emission area in which a portion of a bank is open;
an emission layer contacting the anode electrode in the emission area; and
a cathode pattern electrode that covers N×M (N, M are natural numbers greater than or equal to 2) light emitting elements along an upper surface of the bank, the cathode pattern electrode contacting the emission layer in the emission area,
wherein the cathode pattern electrode is electrically separated from an adjacent cathode pattern electrode by an undercut electrode located in an undercut area of the bank,
wherein an electrical signal is applied through a cathode pattern line that is electrically connected to the cathode pattern electrode.

2. The touch display panel of claim 1, wherein the undercut area includes:
a bank groove in which a portion of the bank is open; and
a pair of undercut electrodes protruding inwardly in an upper portion of the bank groove.

3. The touch display panel of claim 2, wherein the cathode pattern line is in a recessed area on the bank and is in electrical contact with the cathode pattern electrode located thereon.

4. The touch display panel of claim 1, wherein the cathode pattern line and the undercut electrode have a source-drain electrode pattern that constitutes a source electrode and a drain electrode of the driving transistor.

5. The touch display panel of claim 1, wherein the cathode pattern line receives a pixel low-potential voltage during a display driving period and receives a touch driving signal during a touch driving period.

6. The touch display panel of claim 1, wherein the cathode pattern electrode includes a plurality of cathode pattern electrode groups in which cathode pattern lines extend in different directions.

7. The touch display panel of claim 6, wherein the cathode pattern electrode includes:
a first cathode pattern electrode group adjacent to a first non-display area;
a second cathode pattern electrode group adjacent to a second non-display area that is opposite to the first non-display area; and
a third cathode pattern electrode group between the first cathode pattern electrode group and the second cathode pattern electrode group,
wherein the cathode pattern lines include:
a first cathode pattern line extending along the first non-display area, the first cathode pattern line connected to the first cathode pattern electrode group;
a second cathode pattern line extending along the second non-display area, the second cathode pattern line connected to the second cathode pattern electrode group; and
a third cathode pattern line extending along a display area, the third cathode pattern line connected to the third cathode pattern electrode group.

8. The touch display panel of claim 2, wherein the cathode pattern line has a protruding shape on the bank and is in electrical contact with the cathode pattern electrode located thereon.

9. The touch display panel of claim 2, wherein the cathode pattern line is on a planarization layer within a groove in which a portion of the bank is etched, and is in electrical contact with the cathode pattern electrode located thereon.

10. The touch display panel of claim 1, wherein the undercut area includes:
a bank groove in which a portion of the bank is open; and
a pair of undercut electrodes in an inside of the bank in a lower portion of the bank groove.

11. The touch display panel of claim 10, wherein the cathode pattern line is in a recessed area on the bank and is in electrical contact with the cathode pattern electrode thereon.

12. The touch display panel of claim 10, wherein the cathode pattern line has a protruding shape on the bank and is in electrical contact with the cathode pattern electrode thereon.

13. The touch display panel of claim 10, wherein the cathode pattern line is on a planarization layer within a groove in which a portion of the bank is etched and is in electrical contact with the cathode pattern electrode located thereon.

14. A touch display device comprising:
a display panel including a substrate, a driving transistor over the substrate, and a light emitting element that is connected to the driving transistor and is on the driving transistor;
a driving circuit configured to supply a driving signal to the display panel;
a switch circuit configured to supply a pixel low-potential voltage or a touch driving signal to the display panel; and
a timing controller configured to control the driving circuit and the switch circuit,
wherein the light emitting element comprises:
an anode electrode in an emission area in which a portion of a bank is open;
an emission layer contacting the anode electrode in the emission area; and
a cathode pattern electrode that covers N×M (N, M are natural numbers greater than or equal to 2) light emitting elements along an upper surface of the bank, the cathode pattern electrode contacting the emission layer in the emission area,
wherein the cathode pattern electrode is electrically separated from an adjacent cathode pattern electrode by an undercut electrode that is in an undercut area of the bank,
wherein the pixel low-potential voltage or the touch driving signal is applied to the cathode pattern electrode through a cathode pattern line.

15. The touch display device of claim 14, wherein the switch circuit supplies the pixel low-potential voltage to the cathode pattern electrode during a display driving period and supplies the touch driving signal to the cathode pattern electrode during a touch driving period.
